(19) United States
(12) Patent Application Publication
(10) Pub. No.: US 2012/0293217 A1
(43) Pub. Date: Nov. 22, 2012

(54) FEEDFORWARD ACTIVE DECOUPLING

(75) Inventors: Brian P. Ginsburg, Allen, TX (US); Vijay B. Rentala, Plano, TX (US); Srinath Ramaswamy, Murphy, TX (US); Baher Haroun, Allen, TX (US); Eunyoung Seok, Plano, TX (US)

(73) Assignee: Texas Instruments Incorporated, Dallas, TX (US)

(21) Appl. No.: 13/110,769

(22) Filed: May 18, 2011

(51) Int. Cl. H03B 1/00

(52) U.S. Cl. 327/109

(57) ABSTRACT

There are a variety of duty cycle systems, such as low noise amplifiers or LNAs, that have a large time varying current consumption, and parasitic inductances and resistance (usually from bondwires in the package) that can significantly affect supply currents. Thus, to compensate for these parasitics, a boost circuit is provided that allows for current to be supplied from a separate supply using a feedforward scheme to perform active decoupling.

### TECHNICAL FIELD

The invention relates generally to regulating power supplies and, more particularly, to compensating for supply transients in duty cycle systems.

### BACKGROUND

Turning to FIG. 1, an example of a conventional integrated circuit (IC) 102 can be seen. This IC 102 generally includes an input circuit (which is a low noise amplifier or LNA 108 for this example) that has a large time varying current consumption. As shown in this example, the LNA 108 is represented by NMOS transistor Q1 and resistor R1 that is coupled between two supply rails VDDA and VSS (which are coupled to supply 106) and that receives enable signal EN. Typically, the enable signal EN is comprised of a pulse stream (which is typically on 1 ns out of every 10 ns). In operation, LNA 108 (as well as other input circuits) can suffer from losses due to resistive voltage drops as well as voltage changes due to the package inductances 104, and because the of these package inductances 104, the LNA 108 (or other circuitry) should be activated for a period that is longer than a very short period of time (i.e., 10 ns) provided by enable signal EN to allow the supply transients to settle. Capacitor C1 is often used to perform static decoupling, but, for many applications, this is insufficient. Therefore, there is a need for a method and/or apparatus to perform active decoupling.

Some other conventional circuits are: U.S. Pat. No. 6,414,553; U.S. Pat. No. 7,084,706; U.S. Pat. No. 7,839,129; U.S. Patent Pre-Grant Publ. No. 2009/0066162; and Pant et al., “A Charge-Injection Based Active-Decoupling Technique for Inductive-Supply-Noise Suppression,” IEEE Intl. Solid-State Circuits Conf. 2008, Digest of Technical Papers, pp 416, 417, and 624, Feb. 3-7, 2008.

### SUMMARY

A preferred embodiment of the present invention, accordingly, provides an apparatus. The apparatus comprises a first supply rail; a second supply rail; a third supply rail; a current source that is coupled to the third supply rail; a first capacitor that is coupled between the first and second supply rails; a second capacitor that is coupled to at least one of the first and third supply rails; an input circuit that is coupled between the first and second supply rail and that receives an enable signal; a first transistor having a first passive electrode, a second passive electrode, and a control electrode, wherein the second passive electrode of the first is coupled to the second supply rail, and wherein the control electrode of the first transistor receives the enable signal; and a current mirror that is coupled to the third supply rail, the first supply rail, and the first passive electrode of the first transistor.

In accordance with an embodiment of the present invention, the current mirror further comprises: a second transistor that is coupled between the third supply rail and the first passive electrode of the first transistor, wherein the second transistor has a control electrode, and wherein the second transistor is diode-connected; and a third transistor having a control electrode, wherein the third transistor is coupled between the first and third supply rails and is coupled to the control electrode of the second transistor at its control electrode.

In accordance with an embodiment of the present invention, the second capacitor is coupled between the second and third supply rails.

In accordance with an embodiment of the present invention, the current source further comprises an adjustable current source.

In accordance with an embodiment of the present invention, the apparatus further comprises a low dropout regulator (LDO) that is coupled to the first and third supply rails.

In accordance with an embodiment of the present invention, the input circuit further comprises a low noise amplifier (LNA).

In accordance with an embodiment of the present invention, the second capacitor is coupled between the third transistor and the first supply rail.

In accordance with an embodiment of the present invention, the apparatus further comprises a switch that is coupled between the third transistor and the second supply rail, wherein the switch is controlled by an inverse of the enable signal.

In accordance with an embodiment of the present invention, an apparatus is provided. The apparatus comprises a first supply rail; a second supply rail; a third supply rail; a current source that is coupled to the third supply rail; a first capacitor that is coupled between the first and second supply rails; a second capacitor that is coupled to at least one of the first and third supply rails; an input circuit that is coupled between the first and second supply rail and that receives an enable signal; a first MOS transistor that is coupled to the second supply rail at its source and that receives the enable signal at its gate; and a current mirror that is coupled to the third supply rail, the first supply rail, and the first passive electrode of the first transistor.

In accordance with an embodiment of the present invention, the current mirror further comprises: a second MOS transistor that is coupled to the third supply rail at is source and the drain of the first MOS transistor at its gate and source; and a third MOS transistor that is coupled between the first and third supply rails and that is coupled to the gate of the second MOS transistor at its gate.

In accordance with an embodiment of the present invention, the second capacitor is coupled between the drain of the third MOS transistor and the first supply rail.

In accordance with an embodiment of the present invention, the apparatus further comprises a switch that is coupled between the source of the third MOS transistor and the second supply rail, wherein the switch is controlled by an inverse of the enable signal.

In accordance with an embodiment of the present invention, the first MOS transistor further comprises an NMOS transistor, and wherein the second and third transistors further comprises PMOS transistors.

In accordance with an embodiment of the present invention, the first MOS transistor further comprises a PMOS transistor, and wherein the second and third transistors further comprises NMOS transistors.

In accordance with an embodiment of the present invention, a method is provided. The method comprises replicating a first current that is sourced by an input circuit so as to generate a second current; mirroring the second current so as to provide a second current to the input circuit from a first supply that is coupled to a first supply rail; and providing a third current from a second supply rail that is coupled to a second supply, wherein the third current is the difference between the first and second currents.

In accordance with an embodiment of the present invention, the method further comprises compensating for a ripple on the first supply rail.

In accordance with an embodiment of the present invention, the method further comprises providing a generally constant current to the first supply rail.

In accordance with an embodiment of the present invention, the second supply further comprises an LDO that is coupled to the first supply.

In accordance with an embodiment of the present invention, the method further comprises adjusting a fourth current provided to the first supply rail based at least in part on an output of the LDO.

In accordance with an embodiment of the present invention, the step of providing further comprises: coupling a capacitor between the second supply rail and a third supply rail during a first interval so as to charge the capacitor; and coupling the capacitor between the first supply rail and the input circuit during a second interval.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram of an example of a conventional IC; and

FIGS. 2-4 are diagrams of example of an IC in accordance with an embodiment of the present invention.

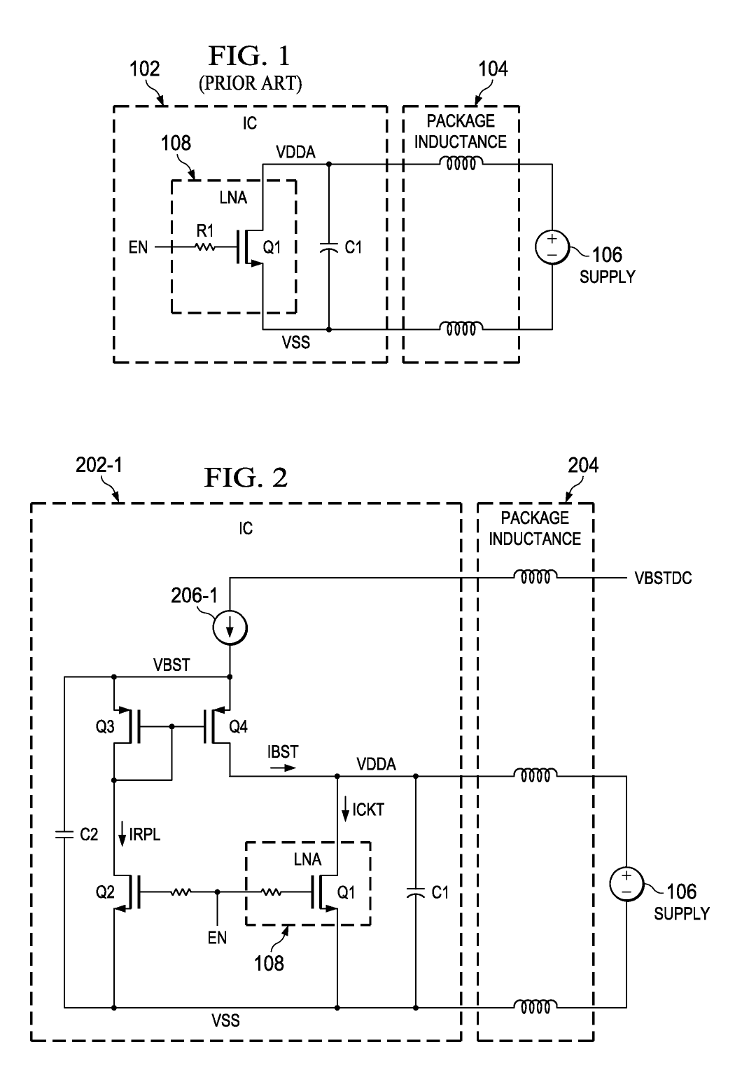

### DETAILED DESCRIPTION

Refer now to the drawings wherein depicted elements are, for the sake of clarity, not necessarily shown to scale and wherein like or similar elements are designated by the same reference numeral through the several views.

Turning to FIG. 2, an example of an IC in accordance with an embodiment of the present invention can be seen. As shown, IC 202-1 has similar components to IC 102, but IC 202-1 also includes a boost circuit that is able to supply current from a supply VBSTDC (which either on-chip or off-chip, but is shown as being off-chip for this example) to compensate for the voltage changes due to the package inductance 204 (usually bondwire inductances) and resistive voltage drops. Supply VBSTDC also generally supplies a higher voltage than supply 106. To accomplish this, a replica circuit (i.e., transistor Q2) is able to source a current from current source 206-1 (which can be a generally constant current source) that is a replica IRPL of the current ICKT sourced by the input circuit (i.e., LNA 108). Typically, transistor Q2 can be between about 1 to N times the size of the transistor receiving the enable signal EN, such as transistor Q1, so that it can have the same or scaled duty cycle current as, for example, transistor Q1 without high frequency signal content. This replica current IRPL can be between 1 and 1/N of the current ICKT sourced by the input circuit (i.e., LNA 108), and this replica current IRPL can be mirrored through a current mirror (i.e., transistors Q3 and Q4) to generate a boost current IBST. As a result of this configuration, the supply 106 supplies a current that is the difference between the currents IBST and ICKT (which is typically much smaller than current ICKT). Additionally, to compensate for any ripple on rail VBST, capacitor C2 is provided (which can be varied in size depending on the desired headroom and ripple amplitude). Transistors Q2 through Q4 may also be NMOS or PMOS transistors or may be comprised of bipolar transistors.

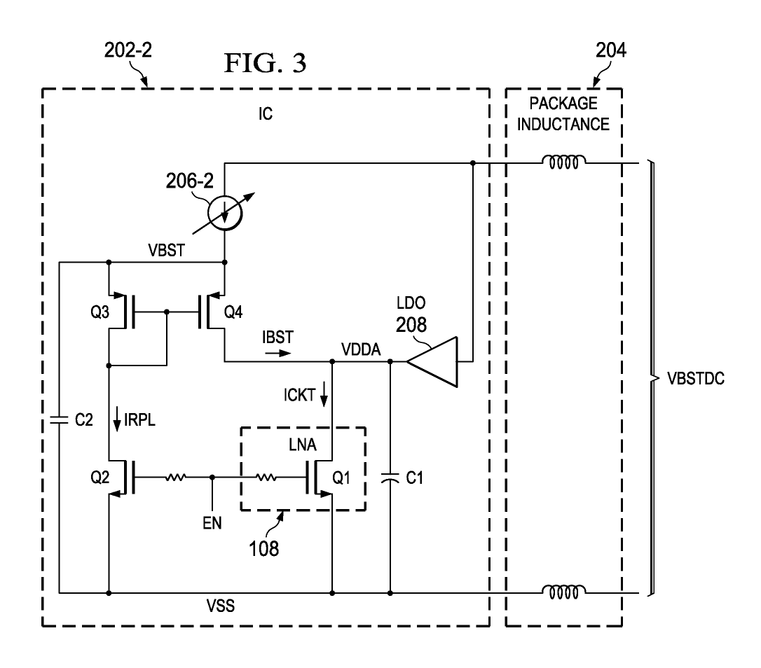

As an alternative, supply 106 can be eliminated in another configuration shown in FIG. 3. Because supply 106 supplies a small current, an on-chip low dropout regulator (LDO) 208 can be used instead to supply this small current (which is the difference between the currents IBST and ICKT). However, because the LDO 208 affects the power supplied by supply VBSTDC, an adjustable current source 206-2 should be used instead of the generally constant current source 206-1 to compensate for the changes due to the LDO 208. Low frequency control loops can be used to control or adjust the current source 206-2. In addition to the LDO 208, a regulator (not shown and which is separate from LDO 208) can be provided to regulate rail VBST.

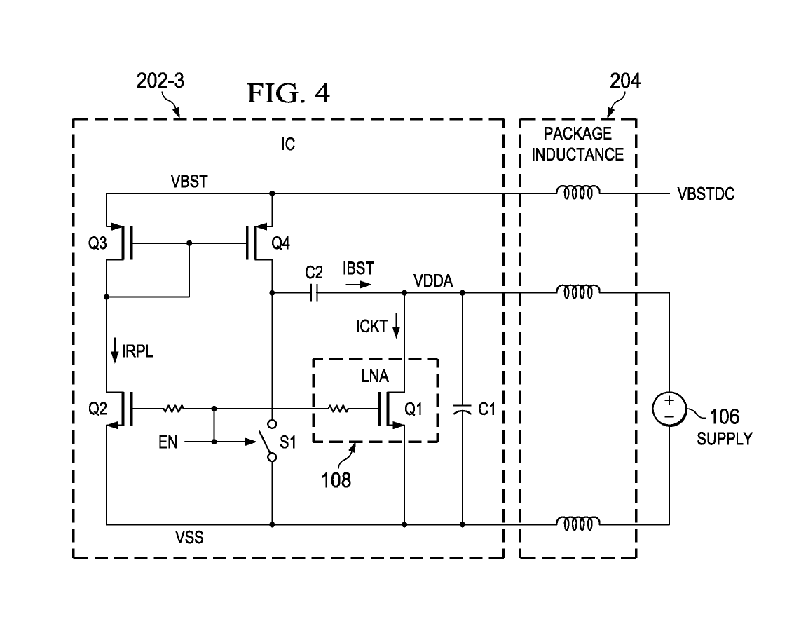

As another alternative, capacitor C2 can be used as a boost capacitor as shown in FIG. 4. Here, a switch S1 is coupled between the drain (or collector) and rail VSS, and capacitor C2 is coupled between the drain (or collector) and rail VDDA. The switch S1 is generally controlled by an inverse of the enable signal EN. When the enable signal EN is logic low or “0,” the switch Si is closed so that charge from rail VDDA can be accumulated on capacitor C2, and when the enable signal EN is logic high or “1” (i.e., during a pulse), the switch S1 is open so that capacitor C2 can boost the current supplied by the current mirror (i.e., transistors Q3 and Q4). By using this arrangement, the current source 206-1 or 206-2 can be eliminated and the supply VBSTDC can supply the same voltage as supply 106, but these supplies VBSTDC and 106 should not share the same bondwire in order to separate the parasitic inductances.

By using the ICs 200-1 to 200-3 several advantages can be realized. Since each IC 200-1 to 200-3 employs a feedforward compensation mechanism, current can be provided on-demand by the input circuit (i.e., LNA 108), avoiding detection or feedback schemes at frequency that would otherwise be employed. Additionally, any regulations loop that may be employed with ICs 200-1 to 200-3 can operate at low frequency.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a first supply rail;
a second supply rail;
a third supply rail;
a first capacitor that is coupled between the first and second supply rails;
a second capacitor that is coupled to at least one of the first and third supply rails;
an input circuit that is coupled between the first and second supply rail and that receives an enable signal, wherein the input circuit is configured to source a current;
a replica circuit that receives the enable signal and that is configured to generate a replica of the current; and
a current mirror that is coupled to the third supply rail, the first supply rail, and the first passive electrode of the first transistor.

2. The apparatus of claim 1, wherein the replica circuit further comprises a first transistor having a first passive electrode, a second passive electrode, and a control electrode, wherein the second passive electrode of the first is coupled to the second supply rail, and wherein the control electrode of the first transistor receives the enable signal.

3. The apparatus of claim 2, wherein the current mirror further comprises:
a second transistor that is coupled between the third supply rail and the first passive electrode of the first transistor, wherein the second transistor has a control electrode, and wherein the second transistor is diode-connected; and
a third transistor having a control electrode, wherein the third transistor is coupled between the first and third supply rails and is coupled to the control electrode of the second transistor at its control electrode.

4. The apparatus of claim 3, wherein the second capacitor is coupled between the second and third supply rails, and wherein the apparatus further comprises a current source that is coupled to the third supply rail.

5. The apparatus of claim 4, wherein the current source further comprises an adjustable current source.

6. The apparatus of claim 5, wherein the apparatus further comprises a low dropout regulator (LDO) that is coupled to the first and third supply rails.

7. The apparatus of claim 6, wherein the input circuit further comprises a low noise amplifier (LNA).

8. The apparatus of claim 3, wherein the second capacitor is coupled between the third transistor and the first supply rail.

9. The apparatus of claim 8, wherein the apparatus further comprises a switch that is coupled between the third transistor and the second supply rail, wherein the switch is controlled by an inverse of the enable signal.

10. An apparatus comprising:
a first supply rail;
a second supply rail;
a third supply rail;
a first capacitor that is coupled between the first and second supply rails;
a second capacitor that is coupled to at least one of the first and third supply rails;
an input circuit that is coupled between the first and second supply rail and that receives an enable signal;
a first MOS transistor that is coupled to the second supply rail at its source and that receives the enable signal at its gate; and
a current mirror that is coupled to the third supply rail, the first supply rail, and the first passive electrode of the first transistor.

11. The apparatus of claim 10, wherein the current mirror further comprises:
a second MOS transistor that is coupled to the third supply rail at is source and the drain of the first MOS transistor at its gate and source; and
a third MOS transistor that is coupled between the first and third supply rails and that is coupled to the gate of the second MOS transistor at its gate.

12. The apparatus of claim 11, wherein the second capacitor is coupled between the second and third supply rails, and wherein the apparatus further comprises a current source that is coupled to the third supply rail.

13. The apparatus of claim 12, wherein the current source further comprises an adjustable current source.

14. The apparatus of claim 13, wherein the apparatus further comprises an LDO that is coupled to the first and third supply rails.

15. The apparatus of claim 14, wherein the input circuit further comprises an LNA.

16. The apparatus of claim 11, wherein the second capacitor is coupled between the drain of the third MOS transistor and the first supply rail.

17. The apparatus of claim 16, wherein the apparatus further comprises a switch that is coupled between the source of the third MOS transistor and the second supply rail, wherein the switch is controlled by an inverse of the enable signal.

18. The apparatus of claim 17, wherein the first MOS transistor further comprises an NMOS transistor, and wherein the second and third transistors further comprises PMOS transistors.

19. The apparatus of claim 17, wherein the first MOS transistor further comprises a PMOS transistor, and wherein the second and third transistors further comprises NMOS transistors.

20. A method comprising:
replicating a first current that is sourced by an input circuit so as to generate a second current;
mirroring the second current so as to provide a second current to the input circuit from a first supply that is coupled to a first supply rail; and
providing a third current from a second supply rail that is coupled to a second supply, wherein the third current is the difference between the first and second currents.

21. The method of claim 20, wherein the method further comprises compensating for a ripple on the first supply rail.

22. The method of claim 21, wherein the method further comprises providing a generally constant current to the first supply rail.

23. The method of claim 21, wherein the second supply further comprises an LDO that is coupled to the first supply.

24. The method of claim 23, wherein the method further comprises adjusting a fourth current provided to the first supply rail based at least in part on an output of the LDO.

25. The method of claim 20, wherein the step of providing further comprises:
coupling a capacitor between the second supply rail and a third supply rail during a first interval so as to charge the capacitor; and
coupling the capacitor between the first supply rail and the input circuit during a second interval.
